(19) United States
(12) Patent Application Publication
(10) Pub. No.: US 2017/0054415 A1
(43) Pub. Date: Feb. 23, 2017

(54) DIFFERENTIAL VOLTAGE REFERENCE BUFFER WITH RESISTOR CHOPPING

(71) Applicant: QUALCOMM Incorporated, San Diego, CA (US)

(72) Inventors: Dongyang Tang, San Diego, CA (US); Vijayakumar Dhanasekaran, San Diego, CA (US)

(21) Appl. No.: 14/830,584

(22) Filed: Aug. 19, 2015

(51) Int. Cl. H03F 1/26; H03F 3/45; H03F 3/387

(52) U.S. Cl. CPC H03F 1/26; H03F 3/387; H03F 3/45071; H03F 2200/21; H03F 2200/252; H03F 2203/45116

(57) ABSTRACT

A voltage reference buffer circuit, including: an amplifier having input terminals and output terminals; a plurality of current sources coupled to the input terminals of the amplifier, the plurality of current sources including a plurality of degeneration resistors coupled to a first plurality of voltage supplies; and a degeneration resistor chopping module comprising a first and second plurality of switches coupled to the plurality of degeneration resistors.

### BACKGROUND

Field

This disclosure relates generally to a voltage reference buffer, and more specifically, to reducing flicker noise in the voltage reference buffer using resistor chopping.

Background

A current-source based voltage reference buffer drives a resistive digital to analog converter (RDAC) used in the receive path of an encoder/decoder (CODEC). To achieve good total harmonic distortion plus noise (THD+N) in the CODEC, the noise of the current-source based voltage reference buffer needs to be low. In particular, the resistor flicker noise can be particularly troublesome as it may be very significant at low frequencies.

FIG. 1 shows a conventional current-source based differential voltage reference buffer 100 including an operational amplifier 110, a positive current source 120, a negative current source 130, and a pair of feedback resistors 140, 142. The reference buffer 100 produces a differential reference voltage (Vref). In FIG. 1, resistor flicker noises generated in the feedback resistors 140, 142 and degeneration resistors in the current sources 120, 130 can be particularly troublesome at low frequencies.

### SUMMARY

The present disclosure describes various implementations of circuits, apparatus, and methods for reducing flicker noise of a differential signal in a voltage reference buffer.

In one embodiment, a voltage reference buffer circuit is disclosed. The circuit includes: an amplifier having input terminals and output terminals; a plurality of current sources coupled to the input terminals of the amplifier, the plurality of current sources including a plurality of degeneration resistors coupled to a first plurality of voltage supplies; and a degeneration resistor chopping module comprising a first and second plurality of switches coupled to the plurality of degeneration resistors.

In another embodiment, a method of reducing flicker noise of a differential signal in a voltage reference buffer is disclosed. The method includes: frequency chopping a plurality of degeneration resistors by configuring first and second pluralities of switches; controlling the first plurality of switches with a first clock signal; and controlling the second plurality of switches with a second clock signal, wherein the first and second clock signals are complementary signals.

In a further embodiment, a method for reducing flicker noise of a differential signal in a voltage reference buffer is disclosed. The method includes: frequency chopping a plurality of degeneration resistors by synchronously reversing polarity of the differential signal on the plurality of degeneration resistors at a chopping frequency to move the differential signal to higher frequencies; configuring a first plurality of switches controlled by a first clock signal; and configuring a second plurality of switches controlled by a second clock signal, wherein the first and second clock signals are complementary signals.

In yet another embodiment, an apparatus for reducing flicker noise of a differential signal in a voltage reference buffer is disclosed. The apparatus includes: means for frequency chopping a plurality of degeneration resistors of a plurality of current sources of the voltage reference buffer, the means for frequency chopping further comprising means for synchronously reversing polarity of the differential signal on the plurality of degeneration resistors at a first chopping frequency to move at least a portion of the flicker noise in the differential signal to higher frequencies.

Other features and advantages of the present disclosure should be apparent from the present description which illustrates, by way of example, aspects of the disclosure.

### BRIEF DESCRIPTION OF THE DRAWINGS

The details of the present disclosure, both as to its structure and operation, may be gleaned in part by study of the appended further drawings, in which like reference numerals refer to like parts, and in which:

FIG. 1 shows a conventional current-source based differential voltage reference buffer;

FIG. 2 is an exemplary wireless device communicating with a wireless communication system;

FIG. 3 is a functional block diagram of an exemplary wireless device in accordance with one embodiment of the present disclosure;

FIG. 4 is a functional block diagram of a CODEC in accordance with one embodiment of the present disclosure;

FIG. 5A is a functional diagram of a current-source based differential voltage reference buffer in accordance with one embodiment of the present disclosure;

FIG. 5B includes timing diagrams of the two clock signals, clk and clk_{b}.

FIG. 6 is a detailed functional diagram of the two current sources shown in FIG. 5A and interconnections between the two current sources in accordance with one embodiment of the present disclosure; and

FIG. 7 is a functional flow diagram illustrating a method for substantially reducing flicker noise in a voltage reference buffer in accordance with one embodiment of the present disclosure.

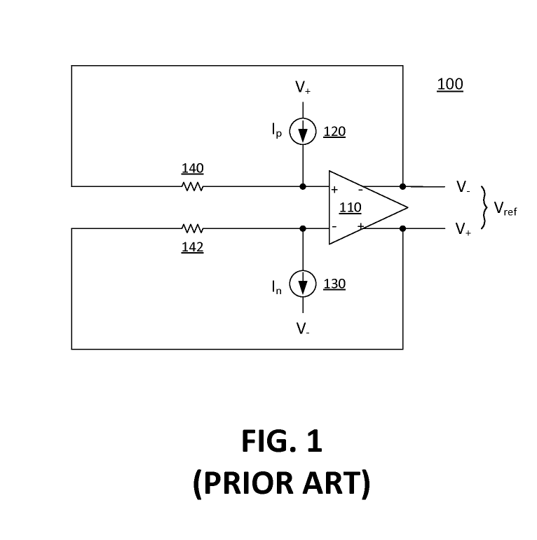

### DETAILED DESCRIPTION

As stated above, flicker noises of a current-source based voltage reference buffer need to be low. The resistor flicker noise can be particularly troublesome as it is very significant at low frequencies. One technique involves moving the noise in the signal to higher frequencies. For example, the signal at the resistors can be chopped with a frequency to carry an alternating current (AC) signal, which can be filtered to attenuate the flicker noise. In one embodiment, a low-pass filter can be used to filter out the noise in the high frequency signals. In another embodiment, for example in audio frequencies, the noise is moved into the high frequency signals and is ignored.

After reading this description it will become apparent how to implement the disclosure in various implementations and applications. Although various implementations of the present disclosure will be described herein, it is understood that these implementations are presented by way of example only, and not limitation. As such, this detailed description of various implementations should not be construed to limit the scope or breadth of the present disclosure.

The term “exemplary” is used herein to mean “serving as an example, instance, or illustration.” Any design described herein as “exemplary” is not necessarily to be construed as preferred or advantageous over other designs. The detailed description includes specific details for the purpose of providing a thorough understanding of the exemplary designs of the present disclosure. It will be apparent to those skilled in the art that the exemplary designs described herein may be practiced without these specific details. In some instances, well-known structures and devices are shown in block diagram form in order to avoid obscuring the novelty of the exemplary designs presented herein.

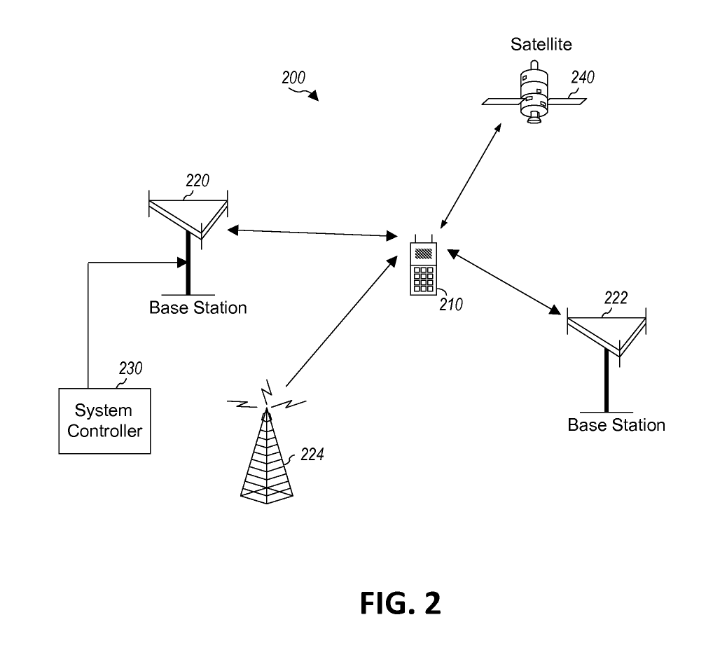

FIG. 2 is an exemplary wireless device 210 communicating with a wireless communication system 200. Wireless communication system 200 may be a Long Term Evolution (LTE) system, a Code Division Multiple Access (CDMA) system, a Global System for Mobile Communications (GSM) system, a wireless local area network (WLAN) system, or some other wireless system. A CDMA system may implement Wideband CDMA (WCDMA), CDMA 1×, Evolution-Data Optimized (EVDO), Time Division Synchronous CDMA (TD-SCDMA), or some other version of CDMA. For simplicity, FIG. 2 shows wireless communication system 200 including two base stations 220 and 222 and one system controller 230. In general, a wireless system may include any number of base stations and any set of network entities.

Wireless device 210 may also be referred to as a user equipment (UE), a mobile station, a terminal, an access terminal, a subscriber unit, a station, etc. Wireless device 210 may be a cellular phone, a smartphone, a tablet, a wireless modem, a personal digital assistant (PDA), a handheld device, a laptop computer, a smartbook, a netbook, a cordless phone, a wireless local loop (WLL) station, a Bluetooth device, etc. Wireless device 210 may communicate with wireless system 200. Wireless device 210 may also receive signals from broadcast stations (e.g., broadcast station 224), signals from satellites (e.g., satellite 240) in one or more global navigation satellite systems (GNSS), etc. Wireless device 210 may support one or more radio technologies for wireless communication including LTE, WCDMA, CDMA 1×, EVDO, TD-SCDMA, GSM, 802.11, etc.

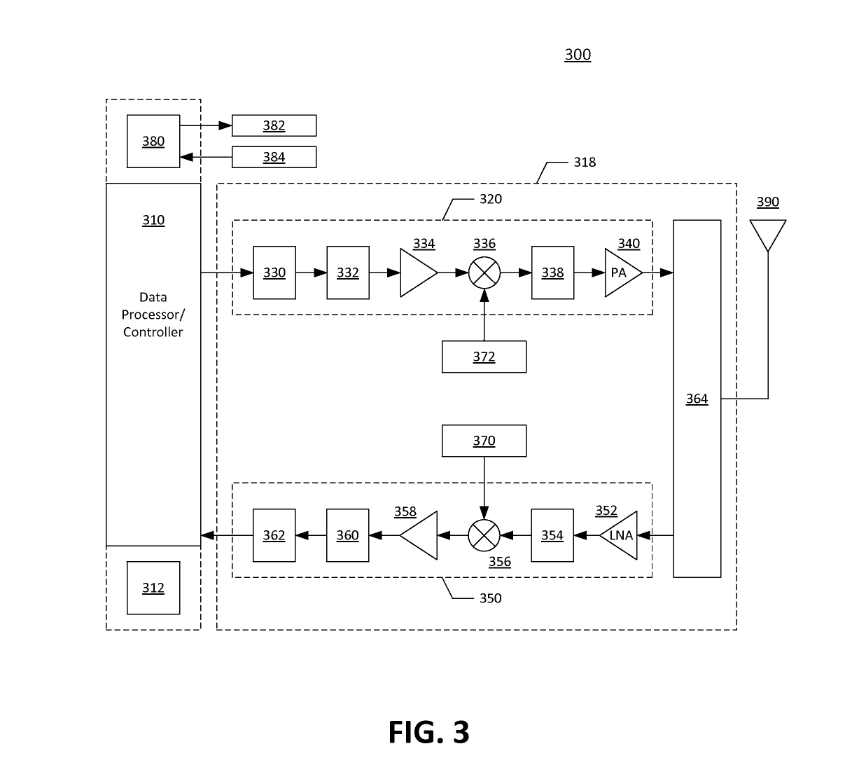

FIG. 3 is a functional block diagram of an exemplary wireless device 300 in accordance with one embodiment of the present disclosure. The wireless device 300 may correspond to the wireless device 210 shown in FIG. 2. The wireless device 300 includes a data processor/controller 310, a transceiver 318, an output device 382, an input device 384, and an antenna 390. The data processor/controller 310 may include the data processor/controller 310 only or the data processor/controller 310, an encoder/decoder (CODEC) 380, and memory 312. The transceiver 318 includes a transmitter 320 and a receiver 350 that support bi-directional communication. The transmitter 320 and/or the receiver 350 may be implemented with a super-heterodyne architecture or direct-conversion architecture. In the super-heterodyne architecture, a signal is frequency converted between radio frequency (RF) and baseband in multiple stages, e.g., from RF to an intermediate frequency (IF) in one stage, and then from IF to baseband in another stage for a receiver. In the direct-conversion architecture, which is also referred to as a zero-IF (ZIF) architecture, a signal is frequency converted between RF and baseband in one stage. The super-heterodyne and direct-conversion architectures may use different circuit blocks and/or have different requirements. In the exemplary design shown in FIG. 3, the transmitter 320 and the receiver 350 are implemented with the direct-conversion architecture.

In the transmit path, the data processor/controller 310 may process (e.g., encode and modulate) data to be transmitted and provide the data to a digital-to-analog converter (DAC) 330. The DAC 330 converts a digital input signal to an analog output signal. The analog output signal is provided to a transmit (TX) baseband (lowpass) filter 332, which may filter the analog output signal to remove images caused by the prior digital-to-analog conversion by the DAC 330. An amplifier 334 may amplify the signal from the TX baseband filter 332 and provide an amplified baseband signal. An upconverter (mixer) 336 may receive the amplified baseband signal and a TX local oscillator (LO) signal from a TX LO signal generator 372. The upconverter 336 may upconvert the amplified baseband signal with the TX LO signal and provide an upconverted signal. A filter 338 may filter the upconverted signal to remove images caused by the frequency upconversion. A power amplifier (PA) 340 may amplify the filtered RF signal from the filter 338 to obtain the desired output power level and provide an output RF signal. The output RF signal may be routed through a duplexer/switch 364.

For frequency-division duplexing (FDD), the transmitter 320 and the receiver 350 may be coupled to the duplexer 364, which may include a transmit (TX) filter for the transmitter 320 and a receive (RX) filter for the receiver 350. The TX filter may filter the output RF signal to pass signal components in a transmit band and attenuate signal components in a receive band. For time-division duplexing (TDD), the transmitter 320 and the receiver 350 may be coupled to the switch 364. The switch 364 may pass the output RF signal from the transmitter 320 to the antenna 390 during uplink time intervals. For both FDD and TDD, the duplexer/switch 364 may provide the output RF signal to the antenna 390 for transmission via a wireless channel.

In the receive path, the antenna 390 may receive signals transmitted by base stations and/or other transmitter stations and may provide a received RF signal. The received RF signal may be routed through duplexer/switch 364. For FDD, the RX filter within the duplexer 364 may filter the received RF signal to pass signal components in a receive band and attenuate signal components in the transmit band. For TDD, the switch 364 may pass the received RF signal from the antenna 390 to the receiver 350 during downlink time intervals. For both FDD and TDD, the duplexer/switch 364 may provide the received RF signal to the receiver 350.

Within the receiver 350, the received RF signal may be amplified by a low noise amplifier (LNA) 352 and filtered by a filter 354 to obtain an input RF signal. A downconverter (mixer) 356 may receive the input RF signal and an RX LO signal from an RX LO signal generator 370. The downconverter 356 may downconvert the input RF signal with the RX LO signal and provide a downconverted signal. The downconverted signal may be amplified by an amplifier 358 and further filtered by an RX baseband (lowpass) filter 360 to obtain an analog input signal. The analog input signal is provided to an analog-to-digital converter (ADC) 362. The ADC 362 converts an analog input signal to a digital output signal. The digital output signal is provided to the data processor/controller 310.

The data processor/controller 310 may perform various functions for the wireless device. For example, the data processor/controller 310 may perform processing for data being transmitted via the transmitter 320 and received via the receiver 350. The data processor/controller 310 may control the operation of various circuits within the transmitter 320 and the receiver 350. The data processor/controller 310 may also interface with output devices 382 (e.g., a speaker) and input devices 384 (e.g., a microphone) through the CODEC 380. The memory 312 may store program codes and data for the data processor/controller 310. The memory 312 may be internal or external to the data processor/controller 310. The memory 312 may be referred to as a computer-readable medium. The data processor/controller 310 may be implemented on one or more application specific integrated circuits (ASICs) and/or other ICs.

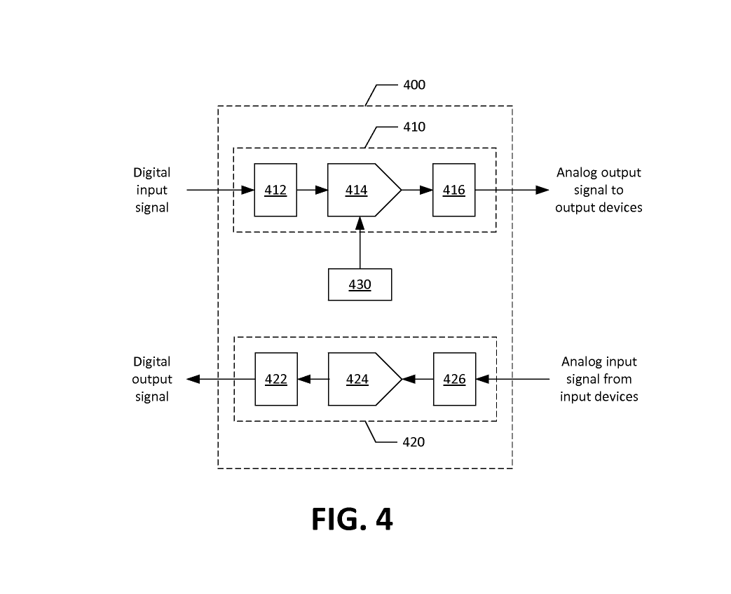

FIG. 4 is a functional block diagram of a CODEC 400 in accordance with one embodiment of the present disclosure. The CODEC 400 may correspond to the CODEC 380 shown in FIG. 3. In the illustrated embodiment of FIG. 4, the CODEC 400 includes a receive channel 410, a transmit channel 420, and a voltage reference buffer 430. The receive channel 410 includes a digital signal processor 412, a DAC 414, and an analog signal processor 416. The digital signal processor 412 receives and processes a digital input signal generated by the data processor/controller 310. The DAC 414 converts the processed digital input signal to an analog signal. The analog signal processor 416 receives and processes the converted analog signal and sends the processed analog signal to the output devices 382. The voltage reference buffer 430 drives the DAC 414 used in the receive channel 410. In one embodiment, the voltage reference buffer 430 is configured as a current-source based differential voltage reference buffer.

The transmit channel 420 includes an analog signal processor 426, an ADC 424, and a digital signal processor 422. The analog signal processor 426 receives and processes an analog input signal from the input devices 384. The ADC 424 converts the processed analog input signal to a digital signal. The digital signal processor 422 receives and processes the converted digital signal and outputs the processed digital signal to the data processor/controller 310.

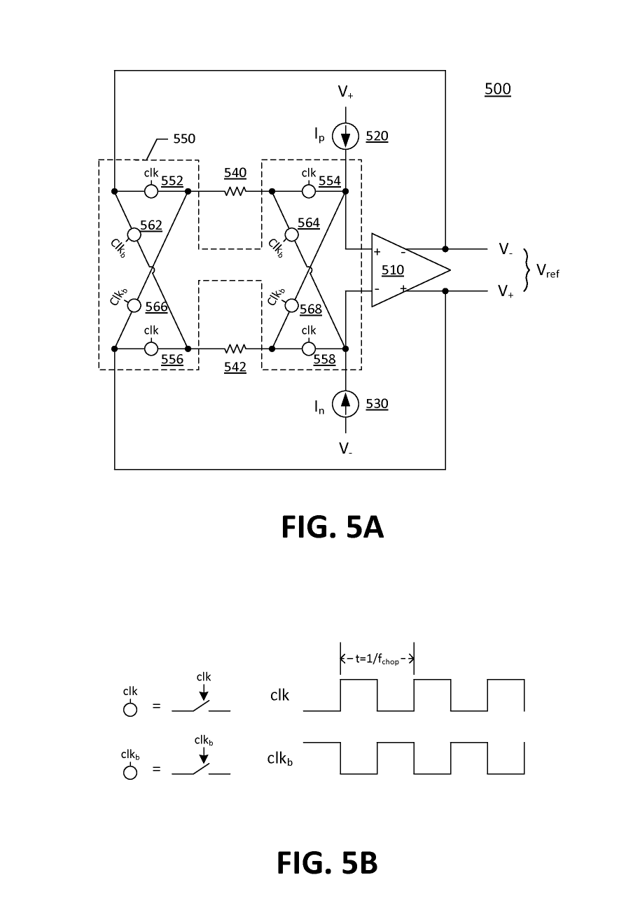

FIG. 5A is a functional diagram of a current-source based differential voltage reference buffer 500 in accordance with one embodiment of the present disclosure. The voltage reference buffer 500 may correspond to the voltage reference buffer 430 shown in FIG. 4. In one embodiment, the current-source based differential voltage reference buffer 500 includes an operational amplifier (op-amp) 510, a positive current source 520, a negative current source 530, and a pair of feedback resistors 540, 542. In another embodiment, more than two feedback resistors can be used with a corresponding number of current sources. The current source 520 connects to the positive input of the op-amp 510, while the current source 530 connects to the negative input of the op-amp 510. To substantially reduce the flicker noise that may be caused by the feedback resistors 540, 542 when the voltages are applied, the current-source based differential voltage reference buffer 500 also includes a feedback resistor chopping module 550.

In the illustrated embodiment of FIG. 5A, the feedback resistor chopping module 550 includes four input switches 552, 562, 566, 556 (i.e., an input portion of the feedback resistor chopping module) and four output switches 554, 564, 568, 558 (i.e., an output portion of the feedback resistor chopping module). Four switches 552, 554, 556, 558, which provide straight paths for the current, are controlled by clock signal clk. Four switches 562, 564, 566, 568, which provide cross paths for the current, are controlled by clock signal clk_{b}. The chopping is accomplished by the switches 552, 554, 556, 558, 562, 564, 566, 568 synchronously reversing the polarity of the input differential signal (i.e., input signal to the op-amp) at a chopping frequency (f_{chop}).

FIG. 5B includes timing diagrams of the two clock signals, clk and clk_{b}, which determine the chopping frequency (f_{chop}). As illustrated, signals clk and clk_{b} are complementary signals which enable the differential signals to synchronously reverse the polarity around the feedback resistors 540, 542 at the chopping frequency. In one embodiment, the chopping frequency is set at around 200 KHz. In other embodiments, the chopping frequency can be set to any frequency that will provide a configuration for a desired reduction in the flicker noise. By chopping the resistors at the chopping frequency, substantial portion of the flicker noise in the differential signal is moved to higher frequencies, which may be filtered to attenuate the flicker noise. In the alternative, the higher frequency signals (e.g., above 100 KHz to 200 KHz in audio applications) may be ignored since they are not audible.

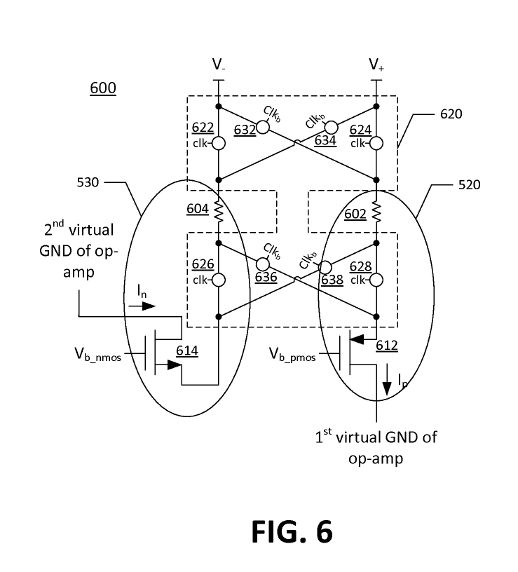

Referring back to FIG. 5A, the current-source based differential voltage reference buffer 500 includes a pair of current sources 520, 530, which also generates a flicker noise through degeneration resistors (e.g., resistors 602, 604 shown in FIG. 6) included in the current sources 520, 530. A degeneration resistor can be used in a common-source amplifier to provide a negative feedback to alleviate problems with unpredictability and distortion in the gain of the amplifier. However, as stated above, the degeneration resistor may generate an unwanted flicker noise. In one embodiment, a degeneration resistor chopping module can be configured in the current-source based differential voltage reference buffer 500 to remove the flicker noise caused by the degeneration resistors.

FIG. 6 is a detailed functional diagram 600 of the two current sources 520, 530 shown in FIG. 5A and interconnections between the two current sources 520, 530 in accordance with one embodiment of the present disclosure. In the illustrated embodiment of FIG. 6, the current source 520 includes a p-type metal oxide semiconductor (PMOS) transistor 612 and a first degeneration resistor 602 coupled to the positive reference voltage (V₊), and the current source 530 includes an n-type metal oxide semiconductor (NMOS) transistor 614 and a second degeneration resistor 604 coupled to the negative reference voltage (V₋).

In the illustrated embodiment of FIG. 6, the PMOS transistor 612 receives a first bias voltage at its gate terminal and draws current Iₚ. The drain terminal of the PMOS transistor 612 couples to a first virtual ground of the op amp. In an alternative, the drain terminal of the PMOS transistor 612 couples to the negative reference voltage. The NMOS transistor 614 receives a second bias voltage at its gate terminal and draws current Iₙ. The drain terminal of the NMOS transistor 614 couples to a second virtual ground of the op amp. In an alternative, the drain terminal of the NMOS transistor 614 couples to the positive reference voltage. The detailed functional diagram 600 also includes a degeneration resistor chopping module 620 configured to substantially reduce the flicker noise produced by the degeneration resistors 602, 604 when the voltages are applied. The source terminals of the PMOS and NMOS transistors couple to the degeneration resistor chopping module 620.

As stated above, the degeneration resistors 602, 604 provide a negative feedback for the common-source amplifier configurations of the PMOS/NMOS transistors 612, 614. In other embodiments, the common-source amplifiers can be configured differently, while providing the same functions. For example, the common-source amplifiers 612, 614 can be configured with different combinations of complementary metal oxide semiconductor (CMOS) transistors, bipolar junction transistors (BJTs), bipolar-CMOS (BiCMOS) transistors, silicon germanium (SiGe) transistors, gallium arsenide (GaAs) transistors, heterojunction bipolar transistors (HBTs), high electron mobility transistors (HEMTs), and silicon-on-insulators (SOIs).

In the illustrated embodiment of FIG. 6, the degeneration resistor chopping module 620 includes four input switches 622, 632, 634, 624 and four output switches 626, 636, 638, 628. Four switches 622, 624, 626, 628, which provide straight paths for the current, are controlled by clock signal clk. Four switches 632, 634, 636, 638, which provide cross paths for the current, are controlled by clock signal clk_{b}. The chopping is accomplished by the switches 622, 624, 626, 628, 632, 634, 636, 638 synchronously reversing the polarity at a chopping frequency. In one embodiment, the switches in the degeneration resistor chopping module 620 are controlled by the same clock signals (clk, clk_{b}) as shown in FIG. 5B. In another embodiment, the switches in the degeneration resistor chopping module 620 are controlled by different clock signals (clk_alt, clk_alt_{b}) than the clock signals (clk, clk_{b}) shown in FIG. 5B. For example, the clock signals clk_alt and clk_alt_{b} are inverted clock signals, while the clock signals (clk_alt, clk_alt_{b}) and (clk, clk_{b}) are different in parameters such as frequency, phase, and duty cycle.

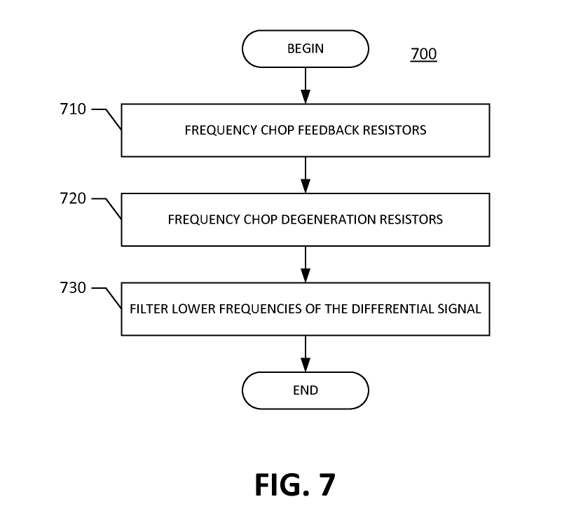

FIG. 7 is a functional flow diagram illustrating a method 700 for substantially reducing flicker noise in a voltage reference buffer in accordance with one embodiment of the present disclosure. In the illustrated embodiment of FIG. 7, the method 700 includes frequency chopping feedback resistors, at block 710, to move the differential signal to a high frequency. The chopping is accomplished by configuring a first plurality of switches to synchronously reverse the polarity on the feedback resistors at the chopping frequency. At block 720, the degeneration resistors of the current sources are frequency chopped. Again, the chopping is accomplished by configuring a second plurality of switches to synchronously reverse the polarity on the degeneration resistors at the chopping frequency.

By chopping the resistors at the chopping frequency, substantial portion of the flicker noise in the differential signal is moved to higher frequencies, which may be filtered to attenuate the flicker noise. Thus, the higher frequency signals are then filtered, at block 730, to attenuate the flicker noise. In the alternative, the higher frequency signals (e.g., above 100 KHz to 200 KHz in audio applications) may be ignored since they are not audible. The range of the higher frequency signals may vary depending on the application of the CODEC. For example, in an audio application, the range of low frequency signals of interest is between 20 Hz and 20 KHz, while in an ultrasonic application, the range of low frequency signals of interest is between 20 Hz and 100 KHz. In either audio or ultrasonic application, signals above 200 KHz would be considered higher frequency signals and are either filtered out (e.g., using a low-pass filter) or ignored.

Although several embodiments of the disclosure are described above, many variations of the disclosure are possible. For example, although the illustrated embodiments of the frequency chopper are configured for a voltage reference buffer, the frequency chopper can be configured for use in other modules such as low noise amplifiers or power amplifiers. Further, features of the various embodiments may be combined in combinations that differ from those described above. Moreover, for clear and brief description, many descriptions of the systems and methods have been simplified. Many descriptions use terminology and structures of specific standards. However, the disclosed systems and methods are more broadly applicable.

Those of skill will appreciate that the various illustrative blocks and modules described in connection with the embodiments disclosed herein can be implemented in various forms. Some blocks and modules have been described above generally in terms of their functionality. How such functionality is implemented depends upon the design constraints imposed on an overall system. Skilled persons can implement the described functionality in varying ways for each particular application, but such implementation decisions should not be interpreted as causing a departure from the scope of the disclosure. In addition, the grouping of functions within a module, block, or step is for ease of description. Specific functions or steps can be moved from one module or block without departing from the disclosure.

The above description of the disclosed embodiments is provided to enable any person skilled in the art to make or use the disclosure. Various modifications to these embodiments will be readily apparent to those skilled in the art, and the generic principles described herein can be applied to other embodiments without departing from the spirit or scope of the disclosure. Thus, it is to be understood that the description and drawings presented herein represent presently preferred embodiments of the disclosure and are therefore representative of the subject matter which is broadly contemplated by the present disclosure. It is further understood that the scope of the present disclosure fully encompasses other embodiments that may become obvious to those skilled in the art and that the scope of the present disclosure is accordingly limited by nothing other than the appended claims.

What is claimed is:

1. A voltage reference buffer circuit, the circuit comprising:
an amplifier having input terminals and output terminals;
a plurality of current sources coupled to the input terminals of the amplifier, the plurality of current sources including a plurality of degeneration resistors coupled to a first plurality of voltage supplies; and
a degeneration resistor chopping module comprising a first and second plurality of switches coupled to the plurality of degeneration resistors.

2. The circuit of claim 1, wherein the plurality of current sources further comprises
a plurality of transistors coupled to the degeneration resistor chopping module.

3. The circuit of claim 2, wherein the plurality of transistors comprises:
a p-type metal oxide semiconductor (PMOS) transistor; and
an n-type metal oxide semiconductor (NMOS) transistor.

4. The circuit of claim 2, wherein drain terminals of the plurality of transistors are coupled to virtual grounds of the amplifier.

5. The circuit of claim 2, wherein the degeneration resistor chopping module includes an input portion and an output portion, the input portion coupled to the plurality of degeneration resistors and the first plurality of voltage supplies, the output portion coupled to the plurality of degeneration resistors and source terminals of the plurality of transistors.

6. The circuit of claim 5, wherein each portion of the input and output portions of the degeneration resistor chopping module comprises:
the first plurality of switches controlled by a first clock signal; and
the second plurality of switches controlled by a second clock signal,
wherein the first and second clock signals are complementary signals.

7. The circuit of claim 6, wherein the first plurality of switches provides straight paths for current through the plurality of degeneration resistors and the second plurality of switches provides cross paths for the current.

8. The circuit of claim 1, wherein the voltage reference buffer circuit is configured to drive a digital-to-analog converter (DAC) in a receive channel of an encoder/decoder (CODEC).

9. The circuit of claim 1, further comprising:
a plurality of feedback resistors coupled to the input and output terminals of the amplifier; and
a feedback resistor chopping module having an input portion and an output portion, the input portion coupled to the plurality of feedback resistors and the output terminals of the amplifier, the output portion coupled to the plurality of feedback resistors and the input terminals of the amplifier.

10. The circuit of claim 9, wherein each portion of the input portion and the output portion of the feedback resistor chopping module comprises:
a first plurality of switches controlled by a first clock signal; and
a second plurality of switches controlled by a second clock signal,
wherein the first and second clock signals are complementary signals.

11. The circuit of claim 10, wherein the first plurality of switches provides straight paths for current through the plurality of feedback resistors and the second plurality of switches provides cross paths for the current.

12. A method of reducing flicker noise of a differential signal in a voltage reference buffer, the method comprising:
frequency chopping a plurality of degeneration resistors by configuring first and second pluralities of switches;
controlling the first plurality of switches with a first clock signal; and
controlling the second plurality of switches with a second clock signal,
wherein the first and second clock signals are complementary signals.

13. The method of claim 12, wherein the first plurality of switches provides straight paths for current through the plurality of degeneration resistors and the second plurality of switches provides cross paths for the current.

14. The method of claim 12, wherein frequency chopping a plurality of degeneration resistors comprises
synchronously reversing polarity of the differential signal on the plurality of degeneration resistors at a chopping frequency.

15. The method of claim 14, wherein synchronously reversing polarity of the differential signal on the plurality of degeneration resistors comprises
moving the flicker noise in the differential signal to higher frequencies.

16. The method of claim 12, further comprising
frequency chopping a plurality of feedback resistors by configuring third and fourth pluralities of switches.

17. The method of claim 16, further comprising:
controlling the third plurality of switches with the first clock signal; and
controlling the fourth plurality of switches with the second clock signal.

18. The method of claim 17, wherein the third plurality of switches provides straight paths for current through the plurality of feedback resistors and the fourth plurality of switches provides cross paths for the current.

19. The method of claim 16, wherein frequency chopping a plurality of feedback resistors comprises
synchronously reversing polarity of the differential signal on the plurality of feedback resistors at a chopping frequency.

20. The method of claim 19, wherein synchronously reversing polarity of the differential signal on the plurality of feedback resistors comprises
moving the flicker noise in the differential signal to a higher frequency.

21. A method for reducing flicker noise of a differential signal in a voltage reference buffer, the method comprising:
frequency chopping a plurality of degeneration resistors by synchronously reversing polarity of the differential signal on the plurality of degeneration resistors at a chopping frequency to move the differential signal to higher frequencies;
configuring a first plurality of switches controlled by a first clock signal; and
configuring a second plurality of switches controlled by a second clock signal,
wherein the first and second clock signals are complementary signals.

22. The method of claim 21, wherein the first plurality of switches provides straight paths for current through the plurality of degeneration resistors and the second plurality of switches provides cross paths for the current.

23. The method of claim 21, further comprising
frequency chopping a plurality of feedback resistors by synchronously reversing polarity of the differential signal on the plurality of feedback resistors at the chopping frequency to move the flicker noise in the differential signal to higher frequencies.

24. The method of claim 23, wherein synchronously reversing polarity of the differential signal on the plurality of feedback resistors comprises:
configuring a third plurality of switches controlled by a first clock signal; and
configuring a fourth plurality of switches controlled by a second clock signal.

25. The method of claim 24, wherein the third plurality of switches provides straight paths for current through the plurality of feedback resistors and the fourth plurality of switches provides cross paths for the current.

26. An apparatus for reducing flicker noise of a differential signal in a voltage reference buffer, the apparatus comprising:
means for frequency chopping a plurality of degeneration resistors of a plurality of current sources of the voltage reference buffer, the means for frequency chopping further comprising means for synchronously reversing polarity of the differential signal on the plurality of degeneration resistors at a first chopping frequency to move at least a portion of the flicker noise in the differential signal to higher frequencies.

27. The apparatus of claim 26, further comprising
means for filtering out the higher frequencies of the differential signal.

28. The apparatus of claim 26, further comprising
means for controlling the means for synchronously reversing polarity of the differential signal on the plurality of degeneration resistors using first and second pluralities of switches controlled by first and second clock signals, respectively,
wherein the first and second clock signals are complementary signals.

29. The apparatus of claim 26, further comprising
means for frequency chopping a plurality of feedback resistors including means for synchronously reversing polarity on the plurality of feedback resistors at a second chopping frequency.

30. The apparatus of claim 29, further comprising
means for controlling the means for synchronously reversing polarity on the plurality of feedback resistors using third and fourth pluralities of switches controlled by first and second clock signals, respectively,
wherein the first and second clock signals are complementary signals.
